(19) United States
(12) Patent Application Publication
(10) Pub. No.: US 2022/0073663 A1
(43) Pub. Date: Mar. 10, 2022

(54) ELECTROACTIVE FLUOROPOLYMERS COMPRISING POLARIZABLE GROUPS

(71) Applicants: ARKEMA FRANCE, Colombes (FR); UNIVERSITE DE BORDEAUX, Bordeaux (FR); INSTITUT POLYTECHNIQUE DE BORDEAUX, Talence Cedex (FR); CENTRE NATIONAL DE LA RECHERCHE SCIENTIFIQUE, Paris (FR)

(72) Inventors: Fabrice DOMINGUES DOS SANTOS, Colombes Cedex (FR); Thibaut SOULESTIN, Pierre-Benite (FR); Georges HADZIIOANNOU, Leognan (FR); Eric CLOUTET, Begles (FR); Cyril BROCHON, Merignac (FR); Konstantinos KALLITSIS, Bordeaux (FR)

(73) Assignees: ARKEMA FRANCE, Colombes (FR); UNIVERSITE DE BORDEAUX, Bordeaux (FR); INSTITUT POLYTECHNIQUE DE BORDEAUX, Talence Cedex (FR); CENTRE NATIONAL DE LA RECHERCHE SCIENTIFIQUE, Paris (FR)

(21) Appl. No.: 17/414,459

(22) PCT Filed: Dec. 16, 2019
(86) PCT No.: PCT/FR2019/053075

§ 371 Date: Jun. 16, 2021

(30) Foreign Application Priority Data
Dec. 17, 2018 (FR) 1873054

(51) Int. Cl. C08F 214/22; C09D 127/16; C09D 5/24; H01L 51/00; C09D 11/106; C09D 11/52; H01L 41/193

(52) U.S. Cl. CPC C08F 214/22; C09D 127/16; C09D 5/24; H01L 51/0043; C08F 2800/10; C09D 11/106; C09D 11/52; H01L 41/193; H01L 51/004

(57) ABSTRACT

A copolymer including fluorinated units of formula (I):

—CX₁X₂—CX₃X₄— (I)
in which each of the X₁, X₂, X₃ and X₄ is independently chosen from H, F and alkyl groups including from 1 to 3 carbon atoms which are optionally partially or totally fluorinated; and units of formula (III):

—CX_{A}X_{B}—CX_{C}Z— (III)
in which each of the X_{A}, X_{B} and X_{C} is independently chosen from H, F and alkyl groups including from 1 to 3 carbon atoms which are optionally partially or totally fluorinated, and Z being a polarizable group of formula —Y—Ar—R; Y representing an O atom or an S atom or an NH group, Ar representing an aryl group, and R being a monodentate or bidentate group including from 1 to 30 carbon atoms; and the copolymer having a heat of fusion of greater than or equal to 5 J/g. Also a process, a composition, an ink and a film.

### FIELD OF THE INVENTION

The present invention relates to electroactive fluoropolymers comprising polarizable groups, to a process for preparing same and to films manufactured therefrom.

### TECHNICAL BACKGROUND

Electroactive fluoropolymers or EAFPs are primarily derivatives of polyvinylidene fluoride (PVDF). In this regard, see the article Vinylidene fluoride-and trifluoroethylene-containing fluorinated electroactive copolymers. How does chemistry impact properties? by Soulestin et al., in Prog. Polym. Sci. 2017 (DOI: 10.1016/j.progpolymsci.2017.04.004). These polymers have particularly interesting dielectric and electromechanical properties. The fluorinated copolymers formed from vinylidene fluoride (VDF) and trifluoroethylene (TrFE) monomers are of particular interest on account of their piezoelectric, pyroelectric and ferroelectric properties. They notably allow the conversion of mechanical or thermal energy into electrical energy, or vice-versa.

Some of these fluorinated copolymers also include units obtained from another monomer bearing a chlorine, bromine or iodine substituent, and notably chlorotrifluoroethylene (CTFE) or chlorofluoroethylene (CFE). Such copolymers have a useful set of properties, namely relaxor ferroelectric nature (characterized by a dielectric constant maximum, as a function of temperature, which is broad and dependent on the frequency of the electric field), a high dielectric constant, a high saturation polarization, and a semicrystalline morphology.

EAFPs have a relatively high dielectric permittivity (greater than 10) for polymer materials. A high dielectric permittivity allows these polymers to be used in the manufacture of electronic devices, notably organic electronic devices and more particularly field-effect transistors or electrocaloric devices. For example, the use of polymers with high dielectric permittivity makes it possible to reduce the electrical consumption of transistors by reducing the voltage that needs to be applied to the gate necessary to make the semiconductor layer conductive.

The review by Ellingford et al. in Macromol. Rapid Commun. 2018 (p. 1800340) concerns modified dielectric elastomers. This review presents various strategies for modifying dielectric elastomers by grafting polar functions along the chain in order to improve the dielectric permittivity of these polymers. The grafting may be performed by hydrosilylation, by addition of a thiol to a double bond, by click chemistry between an alkyne and an azide or by atom-transfer radical polymerization.

The review by Wang et al. in Chem. Rev. 2018 (pages 5690-5754) concerns materials with high dielectric permittivity for flexible transistors. EAFPs are among this category of materials.

The article by Li et al. in Adv. Mater. 2009 (pages 217-221) concerns nanocomposites of ferroelectric polymers with TiO₂ nanoparticles, having a significantly improved electrical energy density, the ferroelectric polymers being VDF copolymers.

The article by Wang et al. in J. Pol. Sci. Part B Polym. Phys. 2011 (pages 1421-1429) describes polymer nanocomposites for electrical energy storage. According to this article, the nanocomposites may comprise PVDF-based polymers and ceramic fillers.

U.S. Pat. No. 7,402,264 describes an electroactive material comprising a composite manufactured from a polymer with polarizable fragments and carbon nanotubes incorporated into the polymer, for the electromechanical functioning of the composite when an external stimulus is applied thereto. The polymer may be, inter alia, PVDF or a P(VDF-TrFE) copolymer.

The article by Zhang et al. in Nature 2002 (pages 284-287) describes an organic composite actuator material with a high dielectric constant. The composite material comprises P(VDF-TrFE) and also copper phthalocyanin oligomers dispersed in the polymer.

US 2016/0145414 concerns a composite comprising at least one ferroelectric organic polymer with relaxation properties which may be, inter alia, PVDF, and at least one phthalate-type plasticizer.

The article by Yin et al. in Eur. Polym. J. 2016 (pages 88-98) describes plasticizer-modified electrostrictive polymers with improved electromechanical performance. Thus, P(VDF-TrFE-CTFE) is used as polymer and bis(2-ethylhexyl) phthalate is used as plasticizer.

There is still a need to provide electroactive fluoropolymers with improved dielectric properties in order to optimize the properties of these polymers, notably in applications such as organic transistors, in electrocaloric devices and in actuators.

### SUMMARY OF THE INVENTION

The invention relates first to a copolymer comprising:
fluorinated units of formula (I):

—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
units of formula (III):

—CX_{A}X_{B}—CX_{C}Z— (III)
in which each of the X_{A}, X_{B} and X_{C} is independently chosen from H, F and alkyl groups comprising from 1 to 3 carbon atoms which are optionally partially or totally fluorinated, and Z being a polarizable group of formula —Y—Ar—R; Y representing an O atom or an S atom or an NH group, Ar representing an aryl group, preferably a phenyl group, and R being a monodentate or bidentate group comprising from 1 to 30 carbon atoms;

and the copolymer having a heat of fusion of greater than or equal to 5 J/g.

In certain embodiments, the copolymer has a heat of fusion of greater than or equal to 6 J/g, preferably greater than or equal to 8 J/g.

In certain embodiments, the units of formula (I) are derived from monomers chosen from vinylidene fluoride, trifluoroethylene and combinations thereof.

In certain embodiments, the fluorinated units of formula (I) comprise both units derived from vinylidene fluoride monomers and units derived from trifluoroethylene monomers, the proportion of units derived from trifluoroethylene monomers preferably being from 15 to 55 mol % relative to the sum of the units derived from vinylidene fluoride and trifluoroethylene monomers.

In certain embodiments, the molar proportion of fluorinated units of formula (I) relative to the total amount of units is less than 99% and preferably less than 95%.

In certain embodiments, the copolymer also comprises fluorinated units of formula (II):

—CX₅X₆—CX₇Z′— (II)

in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

In certain embodiments, the fluorinated units of formula (II) are derived from monomers chosen from chlorotrifluoroethylene and chlorofluoroethylene, notably 1-chloro-1-fluoroethylene.

In certain embodiments, the total molar proportion of units of formulae (II) and (III) relative to the total amount of units is at least 1% and preferably at least 5%.

In certain embodiments, the group Ar is substituted with the group R in the ortho position relative to Y, and/or in the meta-position relative to Y, and/or in the para position relative to Y.

In certain embodiments, the group R comprises a carbonyl function and is preferably chosen from an acetyl group, a substituted or unsubstituted benzoyl group, a substituted or unsubstituted phenylacetyl group, a phthaloyl group, and a phosphine oxide acyl group; the phosphine being substituted with one or more groups chosen from a methyl group, an ethyl group and a phenyl group.

In certain embodiments, the group Ar is a phenyl substituted in the meta position and the group R is an unsubstituted benzoyl group, or the group Ar is a phenyl substituted in the para position and the group R is an unsubstituted benzoyl group, or the group Ar is a phenyl substituted in the para position and the group R is a benzoyl group substituted in the para position with a hydroxyl group, or the group Ar is a phenyl substituted in the meta position and the group R is an acetyl group, or the group Ar is a phenyl substituted in the para position and the group R is an acetyl group, or the group Ar is a phenyl substituted in the ortho position and the group R is a phenylacetyl group substituted a to the carbonyl group with a hydroxyl group, or the group Ar is a phenyl substituted in the meta position and the group R is a phenylacetyl group substituted a to the carbonyl group with a hydroxyl group, or the group Ar is a phenyl substituted in the ortho position and the group R is a phosphine oxide acyl group, or the group Ar is a phenyl substituted in the meta position and the group R is a phosphine oxide acyl group, or the group Ar is a phenyl substituted in the para position and the group R is a phosphine oxide acyl group, or the group Ar is a phenyl substituted in the ortho and meta positions and the group R is a phthaloyl group.

The invention also relates to a process for preparing a copolymer as described above, comprising:
the provision of a starting copolymer comprising fluorinated units of formula (I):

—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
and fluorinated units of formula (II):

—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I;
and placing of the starting copolymer in contact with a polarizable molecule of formula HY—Ar—R; Y representing an O atom or an S atom, or an NH group, Ar representing an aryl group, preferably a phenyl group, and R being a monodentate or bidentate group comprising from 1 to 30 carbon atoms.

In certain embodiments, the placing in contact is performed in a solvent preferably chosen from: dimethyl sulfoxide; dimethylformamide; dimethylacetamide; ketones, notably acetone, methyl ethyl ketone, methyl isobutyl ketone and cyclopentanone; furans, notably tetrahydrofuran; esters, notably methyl acetate, ethyl acetate, propyl acetate, butyl acetate and propylene glycol methyl ether acetate; carbonates, notably dimethyl carbonate; and phosphates, notably triethyl phosphate.

In certain embodiments, the process also comprises a step of reacting the polarizable molecule with a base, before placing the starting copolymer in contact with the polarizable molecule, the base preferably being potassium carbonate.

In certain embodiments, the placing of the starting copolymer in contact with the polarizable molecule is performed at a temperature of from 20 to 120° C. and preferably from 30 to 90° C.

The invention also relates to a composition comprising a first copolymer as described above and a second copolymer different from the first copolymer, the second copolymer also being as described above or the second copolymer being free of polarizable groups and comprising:
fluorinated units of formula (I):

—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated; and
fluorinated units of formula (II):

—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

In certain embodiments, the fluorinated units of formula (I) of the second copolymer are derived from monomers chosen from vinylidene fluoride and/or trifluoroethylene.

In certain embodiments, the second copolymer comprises both fluorinated units of formula (I) derived from vinylidene fluoride monomers and fluorinated units of formula (I) derived from trifluoroethylene monomers, the proportion of units derived from trifluoroethylene monomers being preferably from 15 to 55 mol % relative to the sum of the units derived from vinylidene fluoride and trifluoroethylene monomers.

In certain embodiments, the second copolymer comprises fluorinated units of formula (II) derived from monomers chosen from chlorotrifluoroethylene and chlorofluoroethylene, notably 1-chloro-1-fluoroethylene.

In certain embodiments, the composition comprises from 5% to 95% by weight of first copolymer and from 5% to 95% by weight of second copolymer; preferably from 30% to 70% by weight of first copolymer and from 30% to 70% by weight of second copolymer; the contents being expressed relative to the sum of the first copolymer and the second copolymer.

The invention also relates to an ink comprising the copolymer as described above or comprising the composition as described above, which is a solution or dispersion of the copolymer(s) in a liquid vehicle.

The invention also relates to a process for manufacturing a film, comprising the deposition of a copolymer as described above or of a composition as described above or of the ink as described above onto a substrate.

The invention also relates to a film obtained via the process described above.

The invention also relates to an electronic device comprising a film as described above, the electronic device preferably being chosen from field-effect transistors, memory devices, condensers, sensors, actuators, electromechanical microsystems, electrocaloric devices and haptic devices.

The present invention makes it possible to overcome the drawbacks of the prior art. It more particularly provides electroactive fluoropolymers with improved dielectric properties in order to optimize the properties of these polymers, notably in applications such as organic transistors, in electrocaloric devices and in actuators.

This is accomplished by means of the use of copolymers comprising units bearing polarizable groups. These copolymers are prepared from copolymers bearing leaving groups (Cl, Br or I), which are totally or partly replaced with polarizable groups. This replacement may be performed simply by reacting the copolymer with a polarizable molecule which contains a polarizable group.

The presence of polarizable groups with a high dipole moment makes it possible to increase the polarization of the molecule, which increases its dielectric permittivity and thus improves its dielectric properties when compared with the same polymer not bearing polarizable groups. However, if the polarizable groups are present in an excessive proportion in the polymer, the dielectric permittivity is degraded, since the polymer is insufficiently crystalline. Due to the fact that the copolymer according to the invention has a high heat of fusion of greater than or equal to 5 J/g, it has satisfactory crystallinity despite the presence of the polarizable groups.

Advantageously, a modified polymer bearing polarizable groups may be combined with an unmodified polymer, i.e. a polymer comprising units of formula (I) or a polymer comprising units of formula (I) and of formula (II) and not units of formula (III).

Advantageously also, a first modified polymer bearing polarizable groups may be combined with a second modified polymer bearing polarizable groups, which is different from the first polymer.

These two embodiments are particularly advantageous since they make it possible to obtain a polymer composition of high dielectric permittivity which is stable over a broader temperature range than a single polymer. This advantageous feature is due to the fact that different polymers may have dielectric permittivity maxima at different temperatures.

### BRIEF DESCRIPTION OF THE FIGURES

FIG. 1 is a graph showing the infrared absorbance spectra of a fluoropolymer before (dashed line) and after (continuous line) modification with 4-hydroxybenzophenone. The wavenumber in cm⁻¹ is reported on the x-axis.

FIG. 2 is a graph showing the ¹H NMR spectra of fluoropolymers before and after modification with 4-hydroxybenzophenone. The chemical shift in ppm is reported on the x-axis.

FIG. 3 is a scanning calorimetry analysis thermogram of fluoropolymers before and after modification with 4-hydroxybenzophenone.

The heat flux (exothermic direction upward) is reported on the y-axis and the temperature (in ° C.) is reported on the x-axis.

FIG. 4 is a graph showing the change in dielectric permittivity as a function of the temperature at 1 kHz for fluoropolymers before and after modification with 4-hydroxybenzophenone. The dielectric permittivity is reported on the y-axis and the temperature (in ° C.) is reported on the x-axis.

FIG. 5 is a scanning calorimetry analysis thermogram of fluoropolymers before and after modification with 2-hydroxyanthraquinone. The heat flux (exothermic direction upward) is reported on the y-axis and the temperature (in ° C.) is reported on the x-axis.

FIG. 6 is a graph showing the change in dielectric permittivity as a function of the temperature at 1 kHz for fluoropolymers before and after modification with 2-hydroxyanthraquinone. The dielectric permittivity is reported on the y-axis and the temperature (in ° C.) is reported on the x-axis.

### DETAILED DESCRIPTION

The invention is now described in greater detail and in a nonlimiting manner in the description which follows.

The invention is based on the use of fluoropolymers, referred to hereinbelow as FP polymers. These FP polymers may be used as starting polymers modified for grafting with polarizable groups; the fluoropolymers thus modified are referred to hereinbelow as MFP polymers.

### FP Polymer

According to the invention, an FP polymer comprises:
fluorinated units of formula (I):

—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
fluorinated units of formula (II):

—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

The fluorinated units of formula (I) are derived from monomers of formula CX₁X₂═CX₃X₄ and the fluorinated units of formula (II) are derived from monomers of formula CX₅X₆═CX₇Z′.

The fluorinated units of formula (I) include at least one fluorine atom.

The fluorinated units of formula (I) preferably include not more than 5 carbon atoms, more preferably not more than 4 carbon atoms, more preferably not more than 3 carbon atoms, and more preferably it includes 2 carbon atoms.

In certain embodiments, each group X₁, X₂, X₃ and X₄ independently represents an H or F atom or a methyl group optionally including one or more substituents chosen from H and F.

In certain embodiments, each group X₁, X₂, X₃ and X₄ independently represents an H or F atom.

Particularly preferably, the fluorinated units of formula (I) are derived from a fluorinated monomer chosen from vinyl fluoride (VF), vinylidene fluoride (VDF), trifluoroethylene (TrFE), tetrafluoroethylene (TFE), hexafluoropropylene (HFP), trifluoropropenes and notably 3,3,3-trifluoropropene, tetrafluoropropenes and notably 2,3,3,3-tetrafluoropropene or 1,3,3,3-tetrafluoropropene, hexafluoroisobutylene, perfluorobutylethylene, pentafluoropropenes and notably 1,1,3,3,3-pentafluoropropene or 1,2,3,3,3-pentafluoropropene, perfluoroalkyl vinyl ethers and notably those of general formula Rf—O—CF—CF₂, Rf being an alkyl group, preferably of C1 to C4 (preferred examples being perfluoropropyl vinyl ether or PPVE and perfluoromethyl vinyl ether or PMVE).

The most preferred fluoro monomers comprising fluorinated units of formula (I) are vinylidene fluoride (VDF) and trifluoroethylene (TrFE).

The fluorinated units of formula (II) include at least one fluorine atom.

The fluorinated units of formula (II) preferably include not more than 5 carbon atoms, more preferably not more than 4 carbon atoms, more preferably not more than 3 carbon atoms, and more preferably it includes 2 carbon atoms.

In certain embodiments, each group X₅, X₆ and X₇ independently represents an H or F atom or a C1-C3 alkyl group optionally including one or more fluorine substituents; preferably, an H or F atom or a C1-C2 alkyl group optionally including one or more fluorine substituents; and more preferably an H or F atom or a methyl group optionally including one or more fluorine substituents, and Z′ may be chosen from Cl, I and Br.

In certain embodiments, each group X₅, X₆ and X₇ independently represents an H or F atom or a methyl group optionally including one or more substituents chosen from H and F, and Z′ may be chosen from Cl, I and Br. In certain embodiments, each group X₅, X₆ and X₇ independently represents an H or F atom, and Z′ may be chosen from Cl, I and Br.

Particularly preferably, the fluorinated units of formula (II) are derived from a fluoro monomer chosen from bromotrifluoroethylene, chlorofluoroethylene, chlorotrifluoroethylene and chlorotrifluoropropene. Chlorofluoroethylene may denote either 1-chloro-1-fluoroethylene or 1-chloro-2-fluoroethylene. The 1-chloro-1-fluoroethylene isomer is preferred. Chlorotrifluoropropene is preferably 1-chloro-3,3,3-trifluoropropene or 2-chloro-3,3,3-trifluoropropene.

The most preferred fluoro monomers comprising fluorinated units of formula (II) are chlorotrifluoroethylene (CTFE) and chlorofluoroethylene, notably 1-chloro-1-fluoroethylene (CFE).

In certain embodiments, the FP polymer consists of fluorinated units of formula (I) and fluorinated units of formula (II).

In certain preferred variants, the FP polymer is a P(VDF-CTFE) copolymer.

In certain preferred variants, the FP polymer is a P(TrFE-CTFE) copolymer.

In yet other variations, fluorinated units of formula (I) derived from several different fluoro monomers may be present in the FP polymer.

The FP polymer preferably comprises units simultaneously derived from VDF, TrFE and CTFE.

In certain preferred variations, the FP polymer is a P(VDF-TrFE-CTFE) terpolymer.

Alternatively, the FP polymer may comprise units simultaneously derived from VDF, TrFE and CFE.

In certain variations, the FP polymer may be a P(VDF-TrFE-CFE) terpolymer.

In yet other variations, fluorinated units of formula (II) derived from several different fluoro monomers may be present in the FP polymer.

In yet other variants, units derived from one or more additional monomers, further to those mentioned above, may be present in the FP polymer.

The proportion of units derived from TrFE is preferably from 5 to 95 mol %, relative to the sum of the units derived from VDF and TrFE, and notably: from 5 to 10 mol %; or from 10 to 15 mol %; or from 15 to 20 mol %; or from 20 to 25 mol %; or from 25 to 30 mol %; or from 30 to 35 mol %; or from 35 to 40 mol %; or from 40 to 45 mol %; or from 45 to 50 mol %; or from 50 to 55 mol %; or from 55 to 60 mol %; or from 60 to 65 mol %; or from 65 to 70 mol %; or from 70 to 75 mol %; or from 75 to 80 mol %; or from 80 to 85 mol %; or from 85 to 90 mol %; or from 90 to 95 mol %. A range from 15 to 55 mol % is particularly preferred.

The proportion of fluorinated units of formula (I) in the FP polymer (relative to the total amount of units) may be less than 99 mol %, and preferably less than 95 mol %.

The proportion of fluorinated units of formula (I) in the FP polymer (relative to the total amount of units) may range, for example, from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %; or from 50 to 60 mol %; or from 60 to 70 mol %; or from 70 to 80 mol %; or from 80 to 90 mol %; or from 90 to 95 mol %; or from 95 to 99 mol %.

The proportion of fluorinated units of formula (II) in the FP polymer (relative to the total amount of units) may be at least 1 mol %, and preferably at least 5 mol %.

The proportion of fluorinated units of formula (II) in the FP polymer (relative to the total amount of units) may range, for example, from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %; or from 50 to 60 mol %; or from 60 to 70 mol %; or from 70 to 80 mol %; or from 80 to 90 mol %; or from 90 to 95 mol %; or from 95 to 99 mol %. or from 99 to 99.5 mol %.

The molar composition of the units in the FP polymers may be determined by various means such as infrared spectroscopy or Raman spectroscopy. Conventional methods of elemental analysis of carbon, fluorine and chlorine or bromine or iodine elements, such as X-ray fluorescence spectroscopy, make it possible to calculate unambiguously the mass composition of the polymers, from which the molar composition is deduced.

Use may also be made of multinuclear, notably proton (¹H) and fluorine (¹⁹F), NMR techniques, by analysis of a solution of the polymer in a suitable deuterated solvent. The NMR spectrum is recorded on an FT-NMR spectrometer equipped with a multinuclear probe. The specific signals given by the various monomers in the spectra produced according to one or other nucleus are then identified. Thus, for example, the unit derived from TrFE gives, in proton NMR, a specific signal characteristic of the CFH group (at about 5 ppm). The same is true for the CH₂ groups of VDF (broad unresolved peak centred at 3 ppm). The relative integration of the two signals gives the relative abundance of the two monomers, i.e. the VDF/TrFE mole ratio.

Similarly, the —CFH-group of TrFE, for example, gives characteristic and well-isolated signals in fluorine NMR. The combination of the relative integrations of the various signals obtained in proton NMR and in fluorine NMR results in a system of equations whose resolution provides the molar concentrations of the units derived from the various monomers.

Finally, it is possible to combine elemental analysis, for example for the heteroatoms, such as chlorine or bromine or iodine, and NMR analysis. Thus, the content of units derived from CTFE for example can be determined by measuring the chlorine content by elemental analysis.

A person skilled in the art thus has available a range of methods or a combination of methods allowing him to determine, without ambiguity and with the necessary accuracy, the composition of the FP polymers.

The FP polymer is preferably random and linear.

It is advantageously thermoplastic and not, or not very, elastomeric (as opposed to a fluoroelastomer).

The FP polymer may be homogeneous or heterogeneous. A homogeneous polymer has a uniform chain structure, the statistical distribution of the units derived from the various monomers varying very little between the chains. In a heterogeneous polymer, the chains have a distribution of units derived from the various monomers of multimodal or spread-out type. A heterogeneous polymer therefore comprises chains that are richer in a given unit and chains poorer in this unit. An example of a heterogeneous polymer appears in WO 2007/080338.

The FP polymer is an electroactive polymer.

In particular, preferably, it has a dielectric permittivity maximum of 0 to 150° C., preferably of 10 to 140° C. In the case of ferroelectric polymers, this maximum is called the “Curie temperature” and corresponds to the transition from a ferroelectric phase to a paraelectric phase. This temperature maximum, or transition temperature, may be measured by differential scanning calorimetry or by dielectric spectroscopy.

The polymer preferably has a melting point of 90 to 180° C., more particularly of 100 to 170° C. The melting point may be measured by differential scanning calorimetry according to the standard ASTM D3418-15, in second heating with a heating ramp of 10° C./min.

### Manufacture of an FP Polymer

Although the FP polymer can be produced using any known process, such as emulsion polymerization, suspension polymerization and solution polymerization, it may be preferable to use the process described in WO 2010/116105. This process makes it possible to obtain polymers of high molecular weight and of appropriate structuring.

In short, the preferred process comprises the following steps:
loading an initial mixture containing only the fluoro monomer(s) giving the units of formula (I) (without the fluoro monomer(s) giving the units of formula (II)) in a stirred autoclave containing water;
heating the autoclave to a predetermined temperature, close to the polymerization temperature;
injecting a radical polymerization initiator mixed with water into the autoclave, in order to achieve a pressure in the autoclave which is preferably at least 80 bar, so as to form a suspension of the fluorinated monomers giving the units of formula (I) in water;
injecting a second mixture of fluorinated monomer(s) giving the units of formula (I) and of fluorinated monomer(s) giving the units of formula (II) (and optionally of additional monomers, if any) into the autoclave;
as soon as the polymerization reaction begins, continuously injecting said second mixture into the autoclave reactor, in order to maintain the pressure at an essentially constant level, preferably of at least 80 bar.

The radical polymerization initiator may notably be an organic peroxide of peroxydicarbonate type. It is generally used in an amount of 0.1 to 10 g per kilogram of the total monomer charge. The amount used is preferably from 0.5 to 5 g/kg.

The initial mixture advantageously comprises only the fluorinated monomer(s) giving the units of formula (I) in a proportion equal to that of the desired final polymer.

The second mixture advantageously has a composition which is adjusted such that the total composition of monomers introduced into the autoclave, including the initial mixture and the second mixture, is equal or approximately equal to the composition of the desired final polymer.

The weight ratio of the second mixture to the initial mixture is preferably from 0.5 to 2, more preferably from 0.8 to 1.6.

The implementation of this process with an initial mixture and a second mixture makes the process independent of the reaction initiation phase, which is often unpredictable. The polymers thus obtained are in the form of a powder, without crust or skin.

The pressure in the autoclave reactor is preferably from 80 to 110 bar, and the temperature is maintained at a level preferably from 40° C. to 60° C. The second mixture can be injected continuously into the autoclave. It can be compressed before being injected into the autoclave, for example using a compressor or two successive compressors, generally to a pressure greater than the pressure in the autoclave.

After synthesis, the polymer can be washed and dried.

The weight-average molar mass Mw of the polymer is preferably at least 100 000 g·mol⁻¹, preferably at least 200 000 g·mol-1 and more preferably at least 300 000 g·mol⁻¹ or at least 400 000 g·mol⁻¹. It can be adjusted by modifying certain process parameters, such as the temperature in the reactor, or by adding a transfer agent.

The molecular weight distribution can be estimated by SEC (size exclusion chromatography) with dimethylformamide (DMF) as eluent, with a set of 3 columns of increasing porosity. The stationary phase is a styrene-DVB gel. The detection method is based on measurement of the refractive index, and calibration is performed with polystyrene standards. The sample is dissolved at 0.5 g/l in DMF and filtered through a 0.45 μm nylon filter.

### MFP Polymer

The MFP polymer may be manufactured from an FP polymer by reaction with a polarizable molecule of formula HY—Ar—R according to the Williamson reaction, so as to incorporate into the polymer chain polarizable groups of formula —Y—Ar—R, in which Y represents an O atom or an S atom, or an NH group, Ar represents an aryl group, preferably a phenyl group, and R is a monodentate or bidentate group comprising from 1 to 30 carbon atoms.

Thus, the polarizable molecule reacts by replacing the leaving groups (Cl, Br or I), totally or, preferably, only partly.

A polymer is thus obtained comprising units of formula (III):

—CX_{A}X_{B}—CX_{C}Z— (III)

in which each of the X_{A}, X_{B} and X_{C} is independently chosen from H, F and alkyl groups comprising from 1 to 3 carbon atoms which are optionally partially or totally fluorinated, and Z being a polarizable group of formula —Y—Ar—R.

This polymer also preferably comprises fluorinated units of formula (I) and of formula (II) as described above.

The term “monodentate group” means a group which bonds to the group Ar via only one atom of this group R.

The term “bidentate group” means a group which binds to the group Ar via two different atoms of this group R, preferably on two different positions of the group Ar.

In certain embodiments, the group Ar may be substituted with the group R in the ortho position relative to Y, and/or in the meta-position relative to Y, and/or in the para position relative to Y.

The group R may notably comprise from 2 to 20 carbon atoms, or from 3 to 15 carbon atoms, or from 4 to 10 carbon atoms, and more preferably from 6 to 8 carbon atoms.

The group R may comprise an alkyl or aryl or arylalkyl or alkylaryl chain, which may be substituted or unsubstituted. It may comprise one or more heteroatoms chosen from: O, N, S, P, F, Cl, Br, I.

The group R may preferably comprise a carbonyl function and may preferably be chosen from an acetyl group, a substituted or unsubstituted benzoyl group, a substituted or unsubstituted phenylacetyl group, a phthaloyl group, and a phosphine oxide acyl group; the phosphine being optionally substituted notably with one or more groups chosen from a methyl group, an ethyl group and a phenyl group.

In certain embodiments, the only substituent on the group Ar is the group R. In other embodiments, it may also comprise one (or more) additional substituents, comprising from 1 to 30 carbon atoms. The additional substituent may comprise one or more heteroatoms chosen from: O, N, S, P, F, Cl, Br, I. In addition, the additional substituent may be, for example, an aliphatic carbon-based chain. Alternatively, the additional substituent may be a substituted or unsubstituted aryl group, preferably a phenyl group, or an aromatic or non-aromatic heterocycle.

In certain embodiments, the group Ar is a phenyl substituted in the meta position and the group R is an unsubstituted benzoyl group, or the group Ar is a phenyl substituted in the para position and the group R is an unsubstituted benzoyl group, or the group Ar is a phenyl substituted in the para position and the group R is a benzoyl group substituted in the para position with a hydroxyl group, or the group Ar is a phenyl substituted in the meta position and the group R is an acetyl group, or the group Ar is a phenyl substituted in the para position and the group R is an acetyl group, or the group Ar is a phenyl substituted in the ortho position and the group R is a phenylacetyl group substituted a to the carbonyl group with a hydroxyl group, or the group Ar is a phenyl substituted in the meta position and the group R is a phenylacetyl group substituted a to the carbonyl group with a hydroxyl group, or the group Ar is a phenyl substituted in the ortho position and the group R is a phosphine oxide acyl group, or the group Ar is a phenyl substituted in the meta position and the group R is a phosphine oxide acyl group, or the group Ar is a phenyl substituted in the para position and the group R is a phosphine oxide acyl group, or the group Ar is a phenyl substituted in the ortho and meta positions and the group R is a phthaloyl group.

Preferably, Y is an oxygen atom.

Thus, the polarizable molecules may be chosen, for example, from 3-hydroxybenzophenone, 4-hydroxybenzophenone, 1-hydroxyanthraquinone, 2-hydroxyanthraquinone, 3-hydroxyacetophenone, 4-hydroxyacetophenone, 4,4-dihydroxybenzophenone, 2-hydroxybenzoin, 4-hydroxybenzoin, ethyl-(4-hydroxy-2,6-dimethylbenzoyl) phenylphosphinate and (4-hydroxy-4,6-trimethylbenzoyl)(2,4,6-trimethylbenzoyl)phenylphosphine oxide.

The polarizable molecules may also be chosen from: 2-hydroxy-2-methyl-1-phenylpropan-1-one, the phenyl group also being substituted with a hydroxyl group in the ortho, meta or para position relative to the carbonyl group; 2,4,6-trimethylbenzoyldiphenylphosphine oxide, the phenyl group also being substituted with a hydroxyl group in the meta position relative to the carbonyl group; 2,4,6-trimethylbenzoylethylphenylphosphinate, the phenyl group also being substituted with a hydroxyl group in the meta position relative to the carbonyl group; 1-hydroxycyclohexyl phenyl ketone, the phenyl group also being substituted with a hydroxyl group in the ortho, meta or para position relative to the carbonyl group; bis(2,6-dimethoxybenzoyl)-2,4,4-trimethylpentylphosphine oxide, the phenyl group also being substituted with a hydroxyl group in the meta or para position relative to the carbonyl group; 1-[4-(2-hydroxyethoxy)phenyl]-2-hydroxy-2-methyl-1-propan-1-one, the phenyl group also being substituted with a hydroxyl group in the ortho or meta position relative to the carbonyl group; 2,2-dimethoxy-1,2-diphenylethan-1-one, the phenyl group also being substituted with a hydroxyl group in the ortho, meta or para position relative to the carbonyl group; 2-methyl-1[4-(methylthio)phenyl]-2-morpholinopropan-1-one, the phenyl group also being substituted with a hydroxyl group in the ortho or meta position relative to the carbonyl group; and 2,4-diethylthioxanthone, the thioxanthone group also being substituted with a hydroxyl group.

Alternatively, Y may be an NH group.

Thus, the polarizable molecules may also be chosen from: 2-hydroxy-2-methyl-1-phenylpropan-1-one, the phenyl group also being substituted with an amine group in the ortho, meta or para position relative to the carbonyl group; 2,4,6-trimethylbenzoyldiphenylphosphine oxide, the phenyl group also being substituted with an amine group in the meta position relative to the carbonyl group; 2,4,6-trimethylbenzoylethylphenylphosphinate, the phenyl group also being substituted with an amine group in the meta position relative to the carbonyl group; 1-hydroxycyclohexyl phenyl ketone, the phenyl group also being substituted with an amine group in the ortho, meta or para position relative to the carbonyl group; bis(2,6-dimethoxybenzoyl)-2,4,4-trimethylpentylphosphine oxide, the phenyl group also being substituted with an amine group in the meta or para position relative to the carbonyl group; 1-[4-(2-hydroxyethoxy)phenyl]-2-hydroxy-2-methyl-1-propan-1-one, the phenyl group also being substituted with an amine group in the ortho or meta position relative to the carbonyl group; 2,2-dimethoxy-1,2-diphenylethan-1-one, the phenyl group also being substituted with an amine group in the ortho, meta or para position relative to the carbonyl group; 2-methyl-1[4-(methylthio)phenyl]-2-morpholinopropan-1-one, the phenyl group also being substituted with an amine group in the ortho or meta position relative to the carbonyl group; and 2,4-diethylthioxanthone, the thioxanthone group also being substituted with an amine group.

Alternatively, Y may be a sulfur atom.

Thus, the polarizable molecules may also be chosen from: 2-hydroxy-2-methyl-1-phenylpropan-1-one, the phenyl group also being substituted with a thiol group in the ortho, meta or para position relative to the carbonyl group; 2,4,6-trimethylbenzoyldiphenylphosphine oxide, the phenyl group also being substituted with a thiol group in the meta position relative to the carbonyl group; 2,4,6-trimethylbenzoylethylphenylphosphinate, the phenyl group also being substituted with a thiol group in the meta position relative to the carbonyl group; 1-hydroxycyclohexyl phenyl ketone, the phenyl group also being substituted with a thiol group in the ortho, meta or para position relative to the carbonyl group; bis(2,6-dimethoxybenzoyl)-2,4,4-trimethylpentylphosphine oxide, the phenyl group also being substituted with a thiol group in the meta or para position relative to the carbonyl group; 1-[4-(2-hydroxyethoxy)phenyl]-2-hydroxy-2-methyl-1-propan-1-one, the phenyl group also being substituted with a thiol group in the ortho or meta position relative to the carbonyl group; 2,2-dimethoxy-1,2-diphenylethan-1-one, the phenyl group also being substituted with a thiol group in the ortho, meta or para position relative to the carbonyl group; 2-methyl-1[4-(methylthio)phenyl]-2-morpholinopropan-1-one, the phenyl group also being substituted with a thiol group in the ortho or meta position relative to the carbonyl group; and 2,4-diethylthioxanthone, the thioxanthone group also being substituted with a thiol group.

The FP polymer may be converted into an MFP polymer by placing the FP polymer in contact with the polarizable molecule in a solvent in which the FP polymer is dissolved.

The solvent used may notably be dimethylformamide; dimethylacetamide; dimethyl sulfoxide; ketones, notably acetone, methyl ethyl ketone (or butan-2-one), methyl isobutyl ketone and cyclopentanone; furans, notably tetrahydrofuran; esters, notably methyl acetate, ethyl acetate, propyl acetate, butyl acetate and propylene glycol methyl ether acetate; carbonates, notably dimethyl carbonate; and phosphates, notably triethyl phosphate. Mixtures of these compounds may also be used.

The polarizable molecule may be reacted with a base before being placed in contact with the FP polymer in the solvent, so as to deprotonate the polarizable molecule and to form a polarizable anion of formula ⁻Y—Ar—R, in which Y, Ar and R are as defined above.

The base used for deprotonating the polarizable molecule may have a pKa of from 9 to 12.5 and preferably from 10 to 12.

The base used for deprotonating the polarizable molecule is preferably chosen from potassium carbonate, calcium carbonate and sodium carbonate, and is preferably potassium carbonate.

The base may be used in a molar amount of from 1 to 1.25 equivalents, or from 1.25 to 1.5 equivalents, or from 1.5 to 2.0 equivalents, or from 2.0 to 3.0 equivalents, or from 3.0 to 4.0 equivalents, or from 4.0 to 5.0 equivalents, or from 5.0 to 6.0 equivalents, or from 6.0 to 7.0 equivalents, or from 7.0 to 8.0 equivalents relative to the polarizable molecule.

The reaction of the polarizable molecule with the base may be performed in a solvent, as mentioned above.

The solvent used for the reaction of the polarizable molecule with the base may be the same as or different from the solvent used for placing the FP polymer in contact with the polarizable molecule. Preferably, the solvent used for the reaction of the polarizable molecule with the base is the same as that used for placing the FP polymer in contact with the polarizable molecule.

The reaction of the polarizable molecule with the base may be performed at a temperature of from 20 to 80° C., more preferably from 30 to 70° C.

The duration of the reaction of the polarizable molecule with the base may be, for example, from 5 minute to 5 hours, preferably from 15 minutes to 2 hours, more preferably from 30 minutes to 1 hour.

In certain embodiments, the step of reacting the polarizable molecule with the base may be followed by a step of removing the excess base.

The concentration of FP polymer introduced into the reaction medium may be, for example, from 1 to 200 g/I, preferably from 5 to 100 g/I and more preferably from 10 to 50 g/I.

The amount of polarizable molecules introduced into the reaction medium may be adjusted according to the desired degree of replacement of the polarizable groups in the polymer. Thus, this amount may be from 0.1 to 0.2 molar equivalent (of polarizable groups introduced into the reaction medium, relative to the leaving groups Cl, Br or I present in the FP polymer); or from 0.2 to 0.3 molar equivalent; or from 0.3 to 0.4 molar equivalent; or from 0.4 to 0.5 molar equivalent; or from 0.5 to 0.6 molar equivalent; or from 0.6 to 0.7 molar equivalent; or from 0.7 to 0.8 molar equivalent; or from 0.8 to 0.9 molar equivalent; or from 0.9 to 1.0 molar equivalent; or from 1.0 to 1.5 molar equivalents; or from 1.5 to 2 molar equivalents; or from 2 to 5 molar equivalents; or from 5 to 10 molar equivalents; or from 10 to 50 molar equivalents.

The reaction of the FP polymer with the polarizable molecule is preferably performed with stirring.

The reaction of the FP polymer with the polarizable molecule is preferably performed at a temperature of from 20 to 120° C., more preferably from 30 to 90° C. and more particularly from 40 to 80° C.

The duration of the reaction of the FP polymer with the polarizable molecule may be, for example, from 15 minutes to 96 hours, preferably from 1 hour to 84 hours, more preferably from 2 to 72 hours.

When the desired reaction time has been reached, the MFP polymer may be precipitated from a non-solvent, for example deionized water. It may subsequently be filtered and dried.

The composition of the MFP polymer may be characterized by elemental analysis and by NMR, as described above, and also by infrared spectrometry. In particular, valency vibration bands characteristic of the aromatic and carbonyl functions are observed between 1500 and 1900 cm⁻¹.

In certain embodiments, all of the leaving groups Cl, Br or I of the starting FP polymer may be replaced with polarizable groups in the MFP polymer.

Alternatively and preferentially, the leaving groups Cl, Br or I of the starting FP polymer are only partially replaced with polarizable groups in the MFP polymer.

Thus, the molar proportion of leaving groups (for example of groups Cl when using CTFE or CFE) replaced with polarizable groups may be from 0.2 to 5 mol %; or from 5 to 10 mol %; or from 10 to 20 mol %; or from 20 to 30 mol %; or from 30 to 40 mol %; or from 40 to 50 mol %; or from 50 to 60 mol %; or from 60 to 70 mol %; or from 70 to 80 mol %; or from 80 to 90 mol %; or from 90 to 95 mol %; or more than 95 mol %.

Thus, in the MFP polymer, the proportion of residual structural units including a leaving group (Cl or Br or I) (relative to the total amount of structural units in the polymer) may be, for example, from 0.1 to 0.5 mol %; or from 0.5 to 1 mol %; or from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %. Ranges from 1 to 15 mol %, and preferably from 2 to 10 mol %, are particularly preferred.

Alternatively, in the MFP polymer, all the structural units including a leaving group (Cl or Br or I) are modified.

Thus also, in the MFP polymer, the proportion of structural units including a polarizable group (relative to the total amount of structural units in the polymer) may be, for example, from 0.1 to 0.5 mol %; or from 0.5 to 1 mol %; or from 1 to 2 mol %; or from 2 to 3 mol %; or from 3 to 4 mol %; or from 4 to 5 mol %; or from 5 to 6 mol %; or from 6 to 7 mol %; or from 7 to 8 mol %; or from 8 to 9 mol %; or from 9 to 10 mol %; or from 10 to 12 mol %; or from 12 to 15 mol %; or from 15 to 20 mol %; or from 20 to 25 mol %; or from 25 to 30 mol %; or from 30 to 40 mol %; or from 40 to 50 mol %. Ranges from 0.2 to 15 mol %, and preferably from 0.5 to 10 mol %, are particularly preferred.

The MFP polymer is a semi-crystalline polymer.

The MFP polymer is characterized by a heat of fusion of greater than or equal to 5 J/g, preferably greater than or equal to 6 J/g and more preferably greater than or equal to 8 J/g.

Thus, the MFP polymer may have a heat of fusion of from 5 to 7 J/g; or from 7 to 9 J/g; or from 9 to 12 J/g; or from 12 to 15 J/g; or from 15 to 20 J/g; or from 20 to 25 J/g; or from 25 to 30 J/g. The heat of fusion may be determined by differential scanning calorimetry according to the standard ASTM D3418.

The MFP polymer may be characterized by a dielectric permittivity of greater than or equal to 20, preferably greater than or equal to 30 and more preferably greater than or equal to 40. The dielectric permittivity of the modified polymer may be, for example, from 20 to 25; or from 25 to 30; or from 30 to 35; or from 35 to 40; or from 40 to 45; or from 45 to 50; or from 50 to 55; or from 55 to 60; or from 60 to 65; or from 65 to 70; or from 70 to 75; or from 75 to 80; or from 80 to 85; or from 85 to 90; or from 90 to 95; or from 95 to 100; or from 100 to 110; or from 110 to 120; or from 120 to 130; or from 130 to 140; or from 140 to 150 at 1 kHz and at 25° C.

The dielectric constant may be measured using an impedance meter that is capable of measuring the capacitance of the material, following the recommendations of the standard ASTM D150. The dielectric constant is obtained according to the equation:

$${ɛ}_{r} = \frac{t \cdot C}{A \cdot {ɛ}_{0}} ; \qquad [ Math 1 ]$$

in which t is the thickness of the film; A is the area of the analysed part of the film defined by the superposition of two electrodes; co is the vacuum permittivity; and C is the capacitance of the material. Said material is placed between two conductive electrodes.

### Preparation of a Film

A fluoropolymer film according to the invention may be prepared by depositing on a substrate: either solely one or more MFP polymers; or at least one FP polymer and at least one MFP polymer.

If only one or more MFP polymers are used, it is preferable for the replacement of the leaving groups with the polarizable groups to be only partial. If at least one FP polymer is used in combination with at least one MFP polymer, only some or all of the leaving groups of the MFP polymer may have been replaced with polarizable groups.

In particular, an FP polymer can be combined with an MFP polymer obtained from the FP polymer under consideration. An FP polymer may also be combined with an MFP polymer obtained from an FP polymer different from the one combined with the MFP polymer.

According to a preferred embodiment, the film according to the invention is prepared from polymers (MFP and/or FP) which have different Curie temperatures so as to obtain a blend of polymers having a stable dielectric permittivity over a broad temperature range.

Where at least one FP polymer is combined with at least one MFP polymer, the mass proportion of FP polymer(s) relative to the entirety of the FP and MFP polymers may notably be from 5% to 10%; or from 10% to 20%; or from 20% to 30%; or from 30% to 40%; or from 40% to 50%; or from 50% to 60%; or from 60% to 70%; or from 70% to 80%; or from 80% to 90%; or from 90% to 95%.

The MFP (or MFP and FP) polymers may also be combined with one or more other polymers, notably fluoropolymers, more particularly such as a P(VDF-TrFE) copolymer.

The substrate may notably be a glass, silicon, polymer-material or metal surface.

To perform the deposition, one preferred method consists in dissolving or suspending the polymer(s) in a liquid vehicle to form an “ink” composition, which is subsequently deposited on the substrate.

The liquid vehicle is preferably a solvent. This solvent is preferably chosen from: dimethylformamide; dimethylacetamide; dimethyl sulfoxide; ketones, notably acetone, methyl ethyl ketone, methyl isobutyl ketone and cyclopentanone; furans, notably tetrahydrofuran; esters, notably methyl acetate, ethyl acetate, propyl acetate, butyl acetate and propylene glycol methyl ether acetate; carbonates, notably dimethyl carbonate; and phosphates, notably triethyl phosphate. Mixtures of these compounds may also be used.

The total mass concentration of polymers in the liquid vehicle may notably be from 0.1% to 30%, preferably from 0.5% to 20%.

The ink may optionally comprise one or more additives, notably chosen from surface tension modifiers, rheology modifiers, ageing resistance modifiers, adhesion modifiers, pigments or dyes, and fillers (including nanofillers). Preferred additives are notably cosolvents which modify the surface tension of the ink. In particular, in the case of solutions, the compounds may be organic compounds that are miscible with the solvents used. The ink composition may also contain one or more additives which were used for the synthesis of the polymer(s).

The deposition may notably be performed by spin-coating, spray coating, bar coating, dip coating, roll-to-roll printing, screen printing, lithographic printing or inkjet printing.

After deposition, the liquid vehicle is evaporated off.

The fluoropolymer layer thus constituted may have notably a thickness of from 10 nm to 1 mm, preferably from 100 nm to 500 μm, more preferably of 150 nm to 250 μm and more preferably of 500 nm to 50 μm.

In certain embodiments, the fluoropolymer film according to the invention may conserve its relaxor ferroelectric properties. Thus, this film may be characterized by a coercive field of less than 20 MV/m.

The fluoropolymer film may also be characterized by a remanent polarization of less than 30 mC/m², preferably less than 20 mC/m² and preferably less than 15 mC/m².

The fluoropolymer film may also be characterized by a spontaneous polarization of greater than 30 mC/m², preferably greater than 40 mC/m² and preferably greater than 50 mC/m²; measured at an electric field of 150 MV/m and at 25° C.

The coercive field and remanent polarization measurements may be obtained by measuring the polarization curves of the material. Said film is placed between two conductive electrodes and a sinusoidal electric field is then applied. Measurement of the current passing through said film affords access to the polarization curve.

### Manufacture of an Electronic Device

The film according to the invention may be used as a layer in an electronic device.

Thus, one or more additional layers may be deposited on the substrate equipped with the film of the invention, for example one or more layers of polymers, of semiconducting materials or of metals, in a manner known per se.

The term “electronic device” means either a single electronic component, or a set of electronic components, which are capable of performing one or more functions in an electronic circuit.

According to certain variations, the electronic device is more particularly an optoelectronic device, i.e. a device that is capable of emitting, detecting or controlling an electromagnetic radiation.

Examples of electronic devices or, where appropriate, optoelectronic devices to which the present invention relates are transistors (notably field-effect transistors), chips, batteries, photovoltaic cells, light-emitting diodes (LEDs), organic light-emitting diodes (OLEDs), sensors, actuators, transformers, haptic devices, electromechanical microsystems, electrocaloric devices, and detectors.

According to a preferred variant, the film according to the invention may be used as dielectric layer in an organic transistor or as active layer in an electrocaloric device.

According to another variant, the film according to the invention may be used in a sensor, notably a piezoelectric sensor, as an active layer included between two metallic or polymeric electrodes.

The electronic and optoelectronic devices are used in and integrated into numerous electronic devices, items of equipment or sub-assemblies and in numerous objects and applications, such as televisions, mobile telephones, rigid or flexible screens, thin-film photovoltaic modules, lighting sources, energy converters and sensors, etc.

### Example

The example that follows illustrates the invention without limiting it.

0.6 g of P(VDF-TrFE-CTFE) terpolymer of molar composition 61.7/28.3/10 was placed in a first Schlenk tube, followed by 10 mL of acetone. The mixture was stirred until the polymer was dissolved. 4-Hydroxybenzophenone or 2-hydroxyanthraquinone, potassium carbonate and 15 mL of acetone were stirred in a second Schlenk tube under an inert atmosphere for 1 hour at 50° C. After cooling the second solution to room temperature, the contents of the (second) Schlenk tube were filtered through a 1 μm PTFE filter and transferred into the first Schlenk tube, and the first Schlenk tube was heated at a temperature of between 50 and 80° C. for a time of from 4 hours to 3 days. The solution was then cooled and precipitated twice from water acidified with a few drops of hydrochloric acid. The fleecy white solid was then washed twice with ethanol and twice with chloroform. The modified polymer was dried in a vacuum oven at 60° C. overnight.

The various modified polymers were prepared and the results are presented in the table below.

TABLE 1

| | | | | | | Number of | Degree of | | k at |
|---|---|---|---|---|---|---|---|---|---|
| | | | | Reaction | | equivalents of | replacement of | Heat of | 25° C. |
| Sample | | Reaction | | temperature | Polarizable | polarizable | monomer units | fusion | and at |
| name | FP | time | | (° C.) | molecule | molecule | (%) | (J/g) | 1 kHz |
| A | P(VDF-TrFE-CTFE) | — | | — | — | — | 0 | 14 | 33 |
| | 61.7/28.3/10 | | | | | | | | |
| B-1 | P(VDF-TrFE-CTFE) | 4 | h | 50 | 4-hydroxy | 0.3 | 0.4 | 8 | 43 |
| | 61.7/28.3/10 | | | | benzophenone | | | | |
| B-2 | P(VDF-TrFE-CTFE) | 4 | h | 50 | 4-hydroxy | 0.5 | 1 | 5 | 38 |
| | 61.7/28.3/10 | | | | benzophenone | | | | |
| B-3 | P(VDF-TrFE-CTFE) | 3 | days | 50 | 4-hydroxy | 0.5 | 6.5 | 0 | 12 |
| | 61.7/28.3/10 | | | | benzophenone | | | | |
| C-1 | P(VDF-TrFE-CTFE) | 3 | days | 80 | 2-hydroxy | 0.1 | 0.6 | 10 | 50 |
| | 61.7/28.3/10 | | | | anthraquinone | | | | |
| C-2 | P(VDF-TrFE-CTFE) | 3 | days | 80 | 2-hydroxy | 0.3 | 2.3 | 3 | 19 |
| | 61.7/28.3/10 | | | | anthraquinone | | | | |
| C-3 | P(VDF-TrFE-CTFE) | 1 | day | 80 | 2-hydroxy | 0.5 | 6.0 | 0 | 15 |
| | 61.7/28.3/10 | | | | anthraquinone | | | | |
| C-4 | P(VDF-TrFE-CTFE) | 3 | days | 80 | 2-hydroxy | 0.5 | 12.3 | 0 | 8 |
| | 61.7/28.3/10 | | | | anthraquinone | | | | |

The number of equivalents of polarizable molecules is calculated from the total number of monomer units.

The degree of replacement of monomer units corresponds to the percentage corresponding to the number of monomer units bearing polarizable groups relative to the total number of monomer units in the polymer. The degree of replacement is calculated from the integration of the various signals of the ¹H NMR spectrum. The signals between 7 and 8 ppm correspond to the protons of the aromatic nucleus after modification of the polymer; those between 5 and 6 ppm correspond to the protons of the TrFE units.

The degree of replacement of monomer units is defined by the following formula:

$$\frac{{\int }_{7 ppm}^{8 ppm} Protons of the aromatic nuclei \text{/} Number of Ar protons per molecule}{{\int }_{5 ppm}^{6 ppm} CHF of TrFE + \frac{1}{2} {\int }_{2.2 ppm}^{3.7 ppm} {CH}_{2} of VDF + 2 {\int }_{6 ppm}^{6.7 ppm} CH of double bonds} \qquad [ Math 2 ]$$

It is observed that for a P(VDF-TrFE-CTFE) terpolymer, partial replacement of the polarizable groups combined with a sufficient heat of fusion makes it possible to obtain an increase in the dielectric permittivity relative to the unmodified polymer. However, an additional increase in the degree of replacement with polarizable groups has the result of reducing the dielectric permittivity.

The infrared spectrum of polymer B-3 was measured (continuous line) and compared with that of polymer A before modification (dashed line).

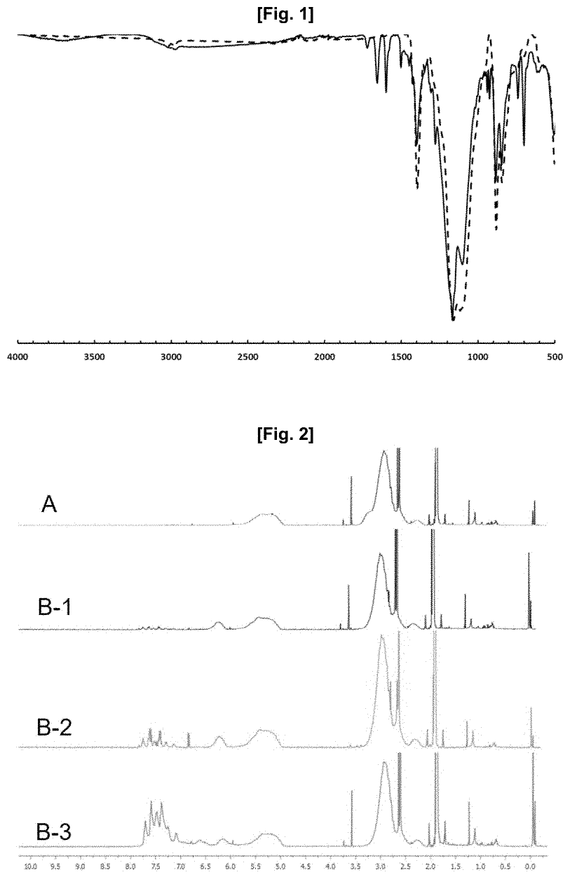

The results can be seen in the graph of FIG. 1. After modification of polymer A, the appearance of the characteristic bands of benzophenone between 1500 and 1700 cm⁻¹ is observed.

The liquid ¹H NMR spectra of polymers A, B-1, B-2 and B-3 were also measured.

The results can be seen in the graph of FIG. 2. After modification of polymer A, the appearance of the characteristic signals between 7 and 8 ppm corresponding to the protons of the aromatic nucleus after modification of the polymer (polymers B-1, B-2 and B-3 relative to the unmodified polymer A) is observed. The absence of the signals between 8 and 10 ppm corresponding to the proton of the phenol function of the polarizable group confirms the grafting of the group onto the polymer.

FIG. 3 is a scanning calorimetry analysis thermogram of the second temperature ramp between −25 and 200° C. at 10° C./minute of the unmodified polymer A and of the modified polymers B-1, B-2 and B-3. A decrease in the heat of fusion and in the melting point are observed when the degree of replacement increases. This indicates a reduction in the degree of crystallinity when the degree of replacement increases, due to the steric hindrance of the polarizable groups which prevent crystallization.

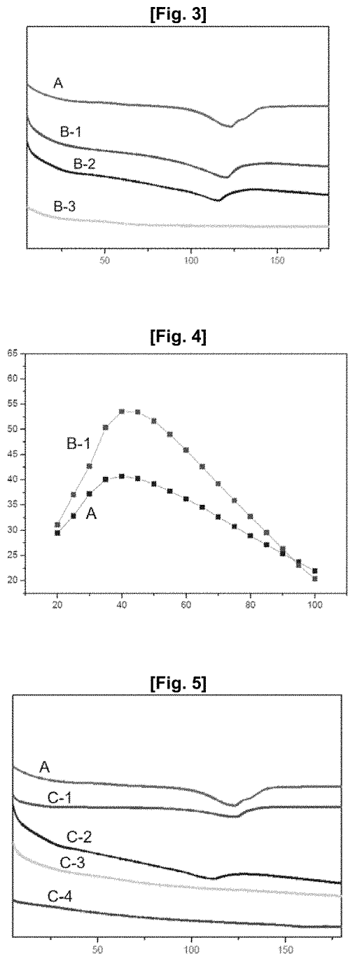

The change in the dielectric permittivity of the unmodified polymer A and of the modified polymer B-1 as a function of the temperature at 1 kHz is shown in FIG. 4. A strong increase in the dielectric permittivity is observed for a degree of replacement of 0.4 (polymer B-1) relative to the unmodified polymer A.

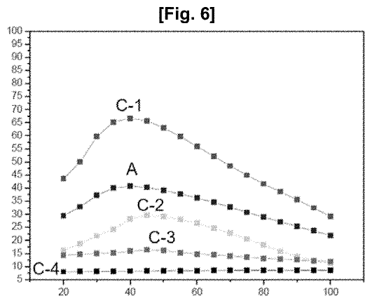

FIG. 5 is a scanning calorimetry analysis thermogram of the second temperature ramp between −25 and 200° C. at 10° C./minute of the unmodified polymer A and of the modified polymers C-1, C-2, C-3 and C-4. A decrease in the heat of fusion and in the melting point are observed when the degree of replacement increases. This indicates a reduction in the degree of crystallinity when the degree of replacement increases, due to the steric hindrance of the polarizable groups which prevent crystallization.

The change in the dielectric permittivity of the unmodified polymer A and of the modified polymers C-1 to C-4 as a function of the temperature at 1 kHz is shown in FIG. 6. A strong increase in the dielectric permittivity is observed for a degree of replacement of 0.6 (polymer C-1) relative to the unmodified polymer A. On the other hand, a decrease in the dielectric permittivity is observed for higher degrees of replacement (polymers C-2, C-3 and C-4). This decrease might be linked to a certain loss of crystallinity.

1. Copolymer comprising
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
units of formula (III):
—CX_{A}X_{B}—CX_{C}Z— (III)
in which each of the X_{A}, X_{B} and X_{C} is independently chosen from H, F and alkyl groups comprising from 1 to 3 carbon atoms which are optionally partially or totally fluorinated, and Z being a polarizable group of formula —Y—Ar—R; Y representing an O atom or an S atom or an NH group, Ar representing an aryl group, and R being a monodentate or bidentate group comprising from 1 to 30 carbon atoms;
and the copolymer having a heat of fusion of greater than or equal to 5 J/g.

2. Copolymer according to claim 1, having a heat of fusion of greater than or equal to 6 J/g.

3. Copolymer according to claim 1, in which the units of formula (I) are derived from monomers chosen from vinylidene fluoride, trifluoroethylene and combinations thereof.

4. Copolymer according to claim 1, in which the fluorinated units of formula (I) comprise both units derived from vinylidene fluoride monomers and units derived from trifluoroethylene monomers, the proportion of units derived from trifluoroethylene monomers being from 15 to 55 mol % relative to the sum of the units derived from vinylidene fluoride and trifluoroethylene monomers.

5. Copolymer according to claim 1, in which the molar proportion of fluorinated units of formula (I) relative to the total amount of units is less than 99%.

6. Copolymer according to claim 1, also comprising fluorinated units of formula (II):
—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

7. Copolymer according to claim 6, in which the fluorinated units of formula (II) are derived from monomers chosen from chlorotrifluoroethylene and chlorofluoroethylene, notably 1-chloro-1-fluoroethylene.

8. Copolymer according to claim 6, in which the total molar proportion of units of formulae (II) and (III) relative to the total amount of units is at least 1%.

9. Copolymer according to claim 1, in which the group Ar is substituted with the group R in the ortho position relative to Y, and/or in the meta-position relative to Y, and/or in the para position relative to Y.

10. Copolymer according to claim 1, in which the group R comprises a carbonyl function.

11. Copolymer according to claim 10, in which the group Ar is a phenyl substituted in the meta position and the group R is an unsubstituted benzoyl group, or the group Ar is a phenyl substituted in the para position and the group R is an unsubstituted benzoyl group, or the group Ar is a phenyl substituted in the para position and the group R is a benzoyl group substituted in the para position with a hydroxyl group, or the group Ar is a phenyl substituted in the meta position and the group R is an acetyl group, or the group Ar is a phenyl substituted in the para position and the group R is an acetyl group, or the group Ar is a phenyl substituted in the ortho position and the group R is a phenylacetyl group substituted a to the carbonyl group with a hydroxyl group, or the group Ar is a phenyl substituted in the meta position and the group R is a phenylacetyl group substituted a to the carbonyl group with a hydroxyl group, or the group Ar is a phenyl substituted in the ortho position and the group R is a phosphine oxide acyl group, or the group Ar is a phenyl substituted in the meta position and the group R is a phosphine oxide acyl group, or the group Ar is a phenyl substituted in the para position and the group R is a phosphine oxide acyl group, or the group Ar is a phenyl substituted in the ortho and meta positions and the group R is a phthaloyl group.

12. Copolymer according to claim 1, the copolymer being a relaxor ferroelectric.

13. Process for preparing a copolymer according to claim 1, comprising:
the provision of a starting copolymer comprising fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
and fluorinated units of formula (II):
—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I;
and placing of the starting copolymer in contact with a polarizable molecule of formula HY—Ar—R; Y representing an O atom or an S atom, or an NH group, Ar representing an aryl group, and R being a monodentate or bidentate group comprising from 1 to 30 carbon atoms.

14. Process according to claim 13, in which the placing in contact is performed in a solvent chosen from: dimethyl sulfoxide; dimethylformamide; dimethylacetamide; ketones; furans, notably tetrahydrofuran; esters; carbonates; and phosphates.

15. Process according to claim 13, also comprising a step of reacting the polarizable molecule with a base, before placing the starting copolymer in contact with the polarizable molecule.

16. Process according to claim 13, in which the placing of the starting copolymer in contact with the polarizable molecule is performed at a temperature of from 20 to 120° C.

17. Composition comprising a first copolymer according to claim 1 and a second copolymer different from the first copolymer, the second copolymer being a copolymer comprising
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
units of formula (III):
—CX_{A}X_{B}—CX_{C}Z— (III)
in which each of the X_{A}, X_{B} and X_{C} is independently chosen from H, F and alkyl groups comprising from 1 to 3 carbon atoms which are optionally partially or totally fluorinated, and Z being a polarizable group of formula —Y—Ar—R; Y representing an O atom or an S atom or an NH group, Ar representing an aryl group, and R being a monodentate or bidentate group comprising from 1 to 30 carbon atoms;
and the second copolymer having a heat of fusion of greater than or equal to 5 J/g,
or the second copolymer being free of polarizable groups and comprising:
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated; and
fluorinated units of formula (II):
—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I.

18. Composition according to claim 17, in which the fluorinated units of formula (I) of the second copolymer are derived from monomers chosen from vinylidene fluoride and/or trifluoroethylene.

19. Composition according to claim 17, in which the second copolymer comprises both fluorinated units of formula (I) derived from vinylidene fluoride monomers and fluorinated units of formula (I) derived from trifluoroethylene monomers, the proportion of units derived from trifluoroethylene monomers being from 15 to 55 mol % relative to the sum of the units derived from vinylidene fluoride and trifluoroethylene monomers.

20. Composition according to claim 17, in which the second copolymer comprises fluorinated units of formula (II) derived from monomers chosen from chlorotrifluoroethylene and chlorofluoroethylene, notably 1-chloro-1-fluoroethylene.

21. Composition according to claim 17 comprising from 5% to 95% by weight of first copolymer and from 5% to 95% by weight of second copolymer; the amounts being expressed relative to the sum of the first copolymer and the second copolymer.

22. Ink comprising the copolymer according to claim 1 or comprising a composition comprising a first copolymer according to claim 1 and a second copolymer different from the first copolymer, the second copolymer being a copolymer comprising
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
units of formula (III):
—CX_{A}X_{B}—CX_{C}Z— (III)
in which each of the X_{A}, X_{B} and X_{C} is independently chosen from H, F and alkyl groups comprising from 1 to 3 carbon atoms which are optionally partially or totally fluorinated, and Z being a polarizable group of formula —Y—Ar—R; Y representing an O atom or an S atom or an NH group, Ar representing an aryl group, and R being a monodentate or bidentate group comprising from 1 to 30 carbon atoms;
and the second copolymer having a heat of fusion of greater than or equal to 5 J/g,
or the second copolymer being free of polarizable groups and comprising:
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated; and
fluorinated units of formula (II):
—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I,
which is a solution or dispersion of the copolymer(s) in a liquid vehicle.

23. Process for manufacturing a film, comprising the deposition of a copolymer according to claim 1 or of a composition comprising a first copolymer according to claim 1 and a second copolymer different from the first copolymer, the second copolymer being a copolymer comprising
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated;
units of formula (III):
—CX_{A}X_{B}—CX_{C}Z— (III)
in which each of the X_{A}, X_{B} and X_{C} is independently chosen from H, F and alkyl groups comprising from 1 to 3 carbon atoms which are optionally partially or totally fluorinated, and Z being a polarizable group of formula —Y—Ar—R; Y representing an O atom or an S atom or an NH group, Ar representing an aryl group, and R being a monodentate or bidentate group comprising from 1 to 30 carbon atoms;
and the second copolymer having a heat of fusion of greater than or equal to 5 J/g,
or the second copolymer being free of polarizable groups and comprising:
fluorinated units of formula (I):
—CX₁X₂—CX₃X₄— (I)
in which each of the X₁, X₂, X₃ and X₄ is independently chosen from H, F and alkyl groups comprising from 1 to 3 carbon atoms which are optionally partially or totally fluorinated; and
fluorinated units of formula (II):
—CX₅X₆—CX₇Z′— (II)
in which each of the X₅, X₆ and X₇ is independently chosen from H, F and alkyl groups comprising from 1 to 3 carbon atoms which are optionally partially or totally fluorinated, and in which Z′ is chosen from Cl, Br and I
onto a substrate.

24. Film obtained via the process according to claim 23.

25. Electronic device comprising a film according to claim 24, the electronic device.
